(19) United States
(12) Patent Application Publication
(10) Pub. No.: US 2022/0375986 A1
(43) Pub. Date: Nov. 24, 2022

(54) ANTI-REFLECTIVE COATINGS FOR PHOTODIODES OF IMAGE SENSOR PIXELS

(71) Applicant: Apple Inc., Cupertino, CA (US)

(72) Inventors: Gershon Rosenblum, Fremont, CA (US); Erin F. Hanelt, Alameda, CA (US); Xiangli Li, Palo Alto, CA (US)

(21) Appl. No.: 17/738,364

(22) Filed: May 6, 2022

Related U.S. Application Data
(60) Provisional application No. 63/192,453, filed on May 24, 2021.

(51) Int. Cl. H01L 27/146

(52) U.S. Cl. CPC H01L 27/14645; H01L 27/1462; H01L 27/14627

(57) ABSTRACT

An image sensor pixel includes a photodiode, a lens positioned in a light-receiving path of the photodiode, and an anti-reflective coating disposed between the photodiode and the lens and including four layers. The four layers include alternating layers of a higher refractive index material and a lower refractive index material. The higher refractive index material has a refractive index that is higher than the lower refractive index material.

### CROSS-REFERENCE TO RELATED APPLICATION

This application is a nonprovisional and claims the benefit under 35 U.S.C. 119(e) of U.S. Patent Application No. 63/192,453, filed May 24, 2021, the contents of which are incorporated herein by reference as if fully disclosed herein.

### FIELD

The described embodiments generally relate to the construction of image sensor pixels that include photodiodes. More particularly, the described embodiments relate to the construction of anti-reflective coatings for photodiodes.

### BACKGROUND

Many of today's devices include an image sensor. Image sensors (or cameras including image sensors and other components (e.g., mechanical, electromechanical, or optical components for focusing light onto an image sensor)) may be used to acquire photographs, videos, navigation or tracking images (e.g., depth maps or contrast maps), and so on. The types of devices that may include an image sensor include mobile phones, computers, wearable devices, vehicle navigation systems, robots, satellites, home appliances, and so on.

Although image sensor pixels are commonly optimized for maximum light absorption, some of the light that impinges on an imager sensor pixel may be reflected. For example, light may be reflected from an outer lens of an image sensor pixel (e.g., from a microlens disposed over a photodiode), or from various interfaces between disparate layers or structures (e.g., from an interface between a microlens and a planarization layer; from an interface between a planarization layer and a color filter; from an interface between a microlens and a color filter; from an interface between a planarization layer and a photodiode; and so on. In some cases, light may be reflected multiple times, from interfaces or structures that are internal to an image sensor pixel and/or interfaces or structures (lenses and so on) that are external the image sensor pixel. Some of this reflected light may ultimately impinge on, and be sensed by, the image sensor pixel's photodiode. When this reflected light is sensed, it may cause various unwanted image artifacts, such as ghost images or flare. Sensing of the reflected light can be especially detrimental when bright objects (e.g., streetlights, headlights, or sunlight) introduce light into a scene that is generally “low light” (e.g., a night time scene, an indoor scene in which sunlight only enters through a window, and so on), or when an image is captured using an extended exposure time under low light.

### SUMMARY

Embodiments of the systems, devices, methods, and apparatus described in the present disclosure include anti-reflective coatings for photodiodes of image sensor pixels. For example, in some embodiments, a light-receiving surface of a silicon photodiode may be planarized using one or more layers of silicon oxide (e.g., silicon dioxide (SiO₂)). Given the higher index of silicon compared to silicon oxide, reflections of light may be more likely to occur at the silicon-to-silicon oxide interface. To mitigate the chance of reflection, an anti-reflective coating may be deposited on the silicon photodiode. The anti-reflecting coating may be a multi-layer coating including alternating layers of a higher refractive index material (e.g., tantalum pentoxide (Ta₂O₅) or halfium dioxide (HfO₂)) and a lower refractive index material (e.g., a silicon oxide, such as SiO₂). In some embodiments, the anti-reflecting coating may include two layers of the higher refractive index material and two layers of the lower refractive index material.

In a first aspect, an image sensor pixel is described. The image sensor pixel may include a photodiode, a lens positioned in a light-receiving path of the photodiode, and an anti-reflective coating disposed between the photodiode and the lens. The anti-reflective coating may include four layers, including alternating layers of a higher refractive index material and a lower refractive index material, with the higher refractive index material having a refractive index that is higher than the lower refractive index material.

In a second aspect, an image sensor is described. The image sensor may include an array of pixels. At least one pixel in the array of pixels may include a photodiode. A four layer anti-reflective coating may be formed directly on the photodiode and include alternating layers of a higher refractive index material and a lower refractive index material, with the higher refractive index material having a refractive index that is higher than the lower refractive index material.

In a third aspect, an image sensor pixel is described. The image sensor pixel may include a photodiode, a lens positioned in a light-receiving path of the photodiode, and an anti-reflective coating disposed between the photodiode and the lens. The anti-reflective coating may include four layers, including: a first layer having a first refractive index, the first layer positioned closer to the photodiode than the other layers in the four layers; a second layer having a second refractive index, the second refractive index lower than the first refractive index, and the second layer disposed on the first layer with the first layer between the second layer and the photodiode; a third layer having a third refractive index, the third refractive index higher than the second refractive index, and the third layer disposed on the second layer with the second layer between the third layer and the first layer; and a fourth layer having a fourth refractive index, the fourth refractive index lower than the third refractive index, and the fourth layer disposed on the third layer with the third layer between the fourth layer and the second layer.

In addition to the exemplary aspects and embodiments described above, further aspects and embodiments will become apparent by reference to the drawings and by study of the following description.

### BRIEF DESCRIPTION OF THE DRAWINGS

The disclosure will be readily understood by the following detailed description in conjunction with the accompanying drawings, wherein like reference numerals designate like structural elements, and in which:

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

FIGS. 1A and 1B show an example electronic device that may include an image sensor;

FIG. 2 shows a plan view of an example image sensor;

FIG. 3 shows an example elevation of two adjacent image sensor pixels in an image sensor;

FIGS. 4A and 4B show examples of anti-reflective coatings that may be formed on a photodiode of an image sensor pixel; and

FIG. 5 shows an example block diagram of an electronic device.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Reference will now be made in detail to representative embodiments illustrated in the accompanying drawings. It should be understood that the following description is not intended to limit the embodiments to one preferred embodiment. To the contrary, it is intended to cover alternatives, modifications, and equivalents as can be included within the spirit and scope of the described embodiments as defined by the appended claims.

Within an image sensor pixel, the silicon-to-silicon oxide interface formed between a silicon photodiode and a layer of silicon oxide used to planarize the silicon photodiode can be a major contributor to “pixel reflectance,” which is defined herein as a reflectance of light away from the pixel's photodiode. In some cases, pixel reflectance by a silicon photodiode has been reduced by forming a one-layer or two-layer anti-reflective coating on the light-receiving surface of the photodiode. The anti-reflective coating may be designed to have a refractive index that is between the refractive indices of silicon and silicon oxide.

Because there are no patternable optical materials that are both compatible with complementary metal-oxide semiconductor (CMOS) processes and have a refractive index exactly matching that of the silicon-to-silicon oxide interface, the performance of existing anti-reflective coatings across the visible spectrum and image sensor pixel's range of incoming light angles is imperfect, and typically allows a pixel reflectance of a few percent. Although multi-stack anti-reflective coatings having many layers and providing good performance across a broad spectrum and range of incoming light angles are known, these coatings are intended for camera lenses and the like, and are impractical within a CMOS image sensor pixel.

Described herein is a four-layer anti-reflective coating (i.e., an anti-reflective stack) that can provide better performance across the visible spectrum and image sensor pixel's range of incoming light angles (e.g., better performance with respect to a conventional one-layer or two-layer anti-reflective coating). The four layers may include alternating layers of a higher refractive index material and a lower refractive index material, with the higher refractive index material having a refractive index that is higher than the lower refractive index material (and vice versa). In some cases, the lower refractive index material may be silicon dioxide, and the higher refractive index material may be tantalum pentoxide or halfium dioxide. These materials are already commonly used in CMOS processes.

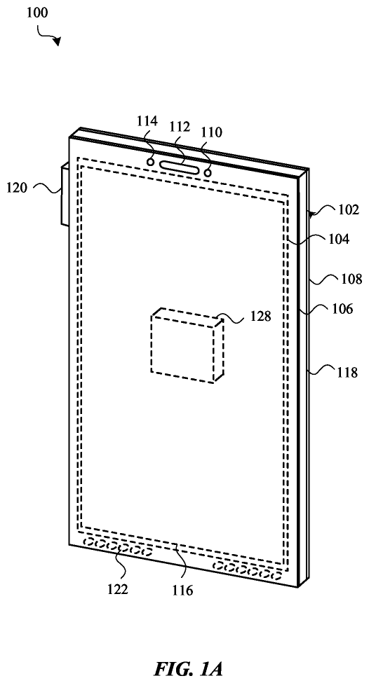

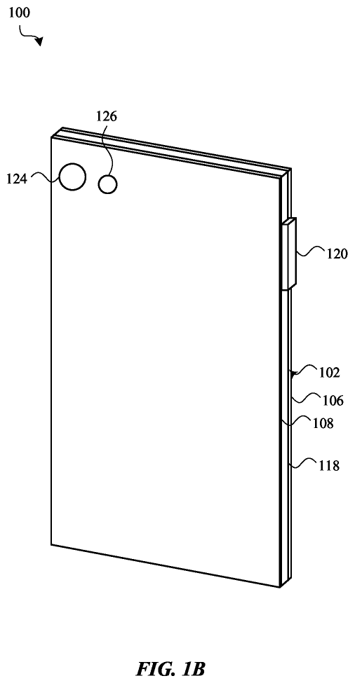

These and other systems, devices, methods, and apparatus are described with reference to FIGS. 1A-5. However, those skilled in the art will readily appreciate that the detailed description given herein with respect to these figures is for explanatory purposes only and should not be construed as limiting.

Directional terminology, such as “top”, “bottom”, “upper”, “lower”, “front”, “back”, “over”, “under”, “above”, “below”, “left”, “right”, etc. is used with reference to the orientation of some of the components in some of the figures described below. Because components in various embodiments can be positioned in a number of different orientations, directional terminology is used for purposes of illustration and is not always limiting. Directional terminology is intended to be construed broadly, and therefore should not be interpreted to preclude components being oriented in different ways. Also, as used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

FIGS. 1A and 1B show an example of a device 100 (an electronic device) that may include any of the image sensors described herein. The device's dimensions and form factor, including the ratio of the length of its long sides to the length of its short sides, suggest that the device 100 is a mobile phone (e.g., a smartphone). However, the device's dimensions and form factor are arbitrarily chosen, and the device 100 could alternatively be any portable electronic device including, for example, a mobile phone, tablet computer, portable computer, portable music player, portable terminal, wearable device, vehicle navigation system, robot navigation system, or other portable or mobile device. The device 100 could also be a device that is semi-permanently located (or installed) at a single location (e.g., a door lock, thermostat, refrigerator, or other appliance). FIG. 1A shows a front isometric view of the device 100, and FIG. 1B shows a rear isometric view of the device 100. The device 100 may include a housing 102 that partially or fully surrounds a display 104. The housing 102 may include or support a front cover 106 or a rear cover 108. The front cover 106 may be positioned over the display 104 and provide a window through which the display 104 (including images displayed thereon) may be viewed by a user. In some embodiments, the display 104 may be attached to (or abut) the housing 102 and/or the front cover 106.

The display 104 may include one or more light-emitting elements or pixels, and in some cases may be a light-emitting diode (LED) display, an organic LED (OLED) display, a liquid crystal display (LCD), an electroluminescent (EL) display, a laser projector, or another type of electronic display. In some embodiments, the display 104 may include, or be associated with, one or more touch and/or force sensors that are configured to detect a touch and/or a force applied to a surface of the front cover 106. In alternative embodiments, the device 100 may not include a display 104, in which case the device may have a front surface that may or may not be associated with one or more touch and/or force sensors. The device 100 may also have touch and/or force sensors associated with other surfaces of the device 100.

The various components of the housing 102 may be formed from the same or different materials. For example, a sidewall 118 of the housing 102 may be formed using one or more metals (e.g., stainless steel), polymers (e.g., plastics), ceramics, or composites (e.g., carbon fiber). In some cases, the sidewall 118 may be a multi-segment sidewall including a set of antennas. The antennas may form structural components of the sidewall 118. The antennas may be structurally coupled (to one another or to other components) and electrically isolated (from each other or from other components) by one or more non-conductive segments of the sidewall 118. The front cover 106 may be formed, for example, using one or more of glass, a crystal (e.g., sapphire), or a transparent polymer (e.g., plastic) that enables a user to view the display 104 through the front cover 106. In some cases, a portion of the front cover 106 (e.g., a perimeter portion of the front cover 106) may be coated with an opaque ink to obscure components included within the housing 102. The rear cover 108 may be formed using the same material(s) that are used to form the sidewall 118 or the front cover 106, or may be formed using a different material or materials. In some cases, the rear cover 108 may be part of a monolithic element that also forms the sidewall 118 (or in cases where the sidewall 118 is a multi-segment sidewall, those portions of the sidewall 118 that are non-conductive). In still other embodiments, all of the exterior components of the housing 102 may be formed from a transparent material, and components within the device 100 may or may not be obscured by an opaque ink or opaque structure within the housing 102.

The front cover 106 may be mounted to the sidewall 118 to cover an opening defined by the sidewall 118 (i.e., an opening into an interior volume in which various electronic components of the device 100, including the display 104, may be positioned). The front cover 106 may be mounted to the sidewall 118 using fasteners, adhesives, seals, gaskets, or other components.

A display stack or device stack (hereafter referred to as a “stack”) including the display 104 (and in some cases the front cover 106) may be attached (or abutted) to an interior surface of the front cover 106 and extend into the interior volume of the device 100. In some cases, the stack may also include a touch sensor (e.g., a grid of capacitive, resistive, strain-based, ultrasonic, or other type of touch sensing elements), or other layers of optical, mechanical, electrical, or other types of components. In some cases, the touch sensor (or part of a touch sensor system) may be configured to detect a touch applied to an outer surface of the front cover 106 (e.g., to a display surface of the device 100).

The stack may also include an image sensor 116 having pixels that are positioned in front of or behind, or interspersed with, the light-emitting elements of the display 104. In some cases, the image sensor 116 may extend across an area equal in size to the area of the display 104. Alternatively, the image sensor 116 may extend across an area that is smaller than or greater than the area of the display 104, or may be positioned entirely adjacent the display 104. Although the image sensor 116 is shown to have a rectangular boundary, the image sensor 116 could alternatively have a boundary with a different shape, including, for example, an irregular shape. The image sensor 116 may be variously configured as an ambient light sensor, an organic light-emitting element diode (e.g., OLED) health sensor (e.g., an OLED age sensor), a touch sensor, a health sensor, a biometric sensor (e.g., a fingerprint sensor or facial recognition sensor), a camera, a depth sensor, and so on. The image sensor 116 may also or alternatively function as a proximity sensor, for determining whether an object (e.g., a finger, face, or stylus) is proximate to the front cover 106. In some embodiments, the image sensor 116 may provide the touch sensing capability (i.e., touch sensor) of the stack.

In some cases, a force sensor (or part of a force sensor system) may be positioned within the interior volume below and/or to the side of the display 104 (and in some cases within the stack). The force sensor (or force sensor system) may be triggered in response to the touch sensor (or touch sensor system) detecting one or more touches on the front cover 106 (or indicating a location or locations of one or more touches on the front cover 106), and may determine an amount of force associated with each touch, or an amount of force associated with the collection of touches as a whole. Alternatively, the touch sensor (or touch sensor system) may be triggered in response to the force sensor (or force sensor system) detecting a force applied to the front cover 106 or elsewhere on the device 100.

As shown primarily in FIG. 1A, the device 100 may include various other components. For example, the front of the device 100 may include one or more front-facing cameras 110 (including one or more image sensors), speakers 112, microphones, or other components 114 (e.g., audio, imaging, and/or sensing components) that are configured to transmit or receive signals to/from the device 100. In some cases, a front-facing camera 110, alone or in combination with other sensors, may be configured to operate as a bio-authentication or facial recognition sensor. Additionally or alternatively, the image sensor 116 may be configured to operate as a front-facing camera, a bio-authentication sensor, or a facial recognition sensor.

The device 100 may also include buttons or other input devices positioned along the sidewall 118 and/or on a rear surface of the device 100. For example, a volume button or multipurpose button 120 may be positioned along the sidewall 118, and in some cases may extend through an aperture in the sidewall 118. The sidewall 118 may include one or more ports 122 that allow air, but not liquids, to flow into and out of the device 100. In some embodiments, one or more sensors may be positioned in or near the port(s) 122. For example, an ambient pressure sensor, ambient temperature sensor, internal/external differential pressure sensor, gas sensor, particulate matter concentration sensor, or air quality sensor may be positioned in or near a port 122.

In some embodiments, the rear surface of the device 100 may include a rear-facing camera 124 (including an image sensor). A flash or light source 126 may also be positioned along the rear of the device 100 (e.g., near the rear-facing camera). In some cases, the rear surface of the device 100 may include multiple rear-facing cameras.

The device 100 may include circuitry 128 (e.g., a processor and/or other components) configured to determine or extract, at least partly in response to signals received directly or indirectly from one or more of the device's sensors, one or more biological parameters of the device's user, a status of the device 100, parameters of an environment of the device 100 (e.g., air quality), a composition of a target or object, or one or more images, for example. In some embodiments, the circuitry 128 may be configured to convey the determined or extracted parameters, statuses, or images via an output device of the device 100. For example, the circuitry 128 may cause the parameters, statuses, or images to be displayed on the display 104, indicated via audio or haptic outputs, transmitted via a wireless communications interface or other communications interface, and so on. The circuitry 128 may also or alternatively maintain or alter one or more settings, functions, or aspects of the device 100, including, in some cases, what is displayed on the display 104.

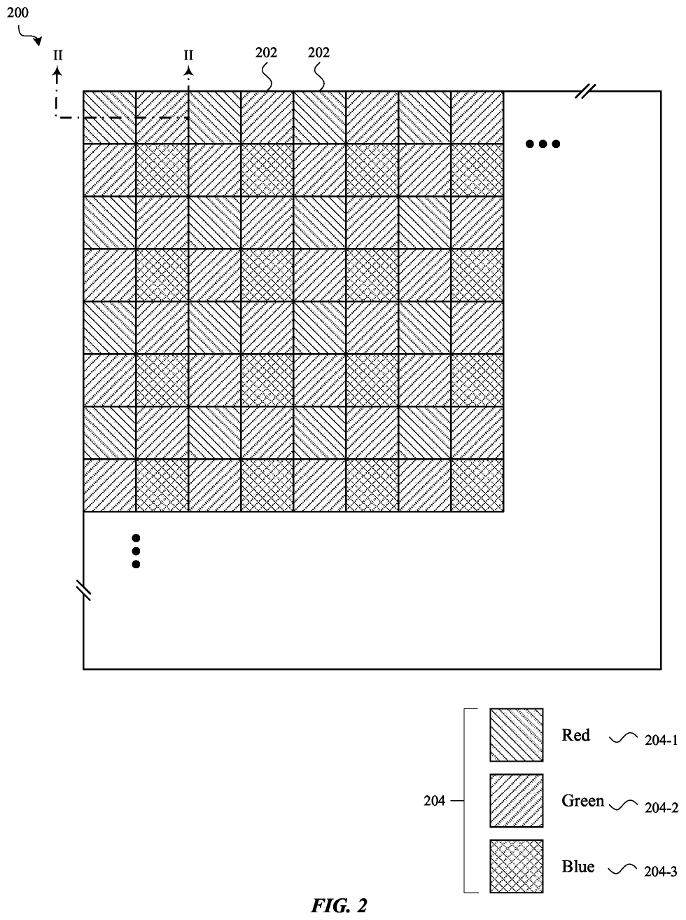

FIG. 2 shows a plan view of an example image sensor 200. In some embodiments, the image sensor 200 may be an image sensor used in one of the cameras described with reference to FIGS. 1A and 1B. In some cases, the image sensor 200 may be a CMOS image sensor.

The image sensor 200 may include an array of pixels (image sensor pixels) 202. The array of pixels 202 may include an optional set of filter elements 204 arranged in a filter pattern. Different subsets of pixels in the array of pixels 202 may receive light through different types of filter elements in the set of filter elements 204. In some embodiments, the different types of filter elements may include red filter elements 204-1, green filter elements 204-2, and blue filter elements 204-3 (i.e., RGB filter elements), which filter elements 204 may function as color filters and be arranged in a Bayer color filter pattern. In some embodiments, the different types of filter elements may include other types of colored filter elements (e.g., cyan-yellow-green-magenta (CYGM) filter elements), or types of filter elements that vary by other than color (e.g., infrared (IR) or ultraviolet (UV) filter elements). Alternatively, the array of pixels 202 may receive unfiltered light, or the array of pixels 202 may receive light that is filtered in the same or similar ways (e.g., filtered in a monochrome manner).

The image sensor 200 may include or be coupled to a singular or distributed controller (e.g., one or more control circuits) for controlling a shutter, exposure, or integration time of the array of pixels 202; for operating the array of pixels 202 in a particular mode (e.g., a high-resolution mode or a high gain mode); for performing a readout of the array of pixels 202; and so on.

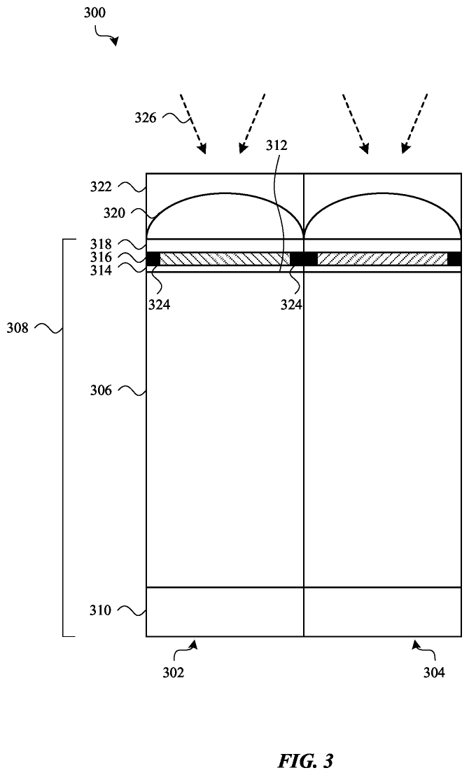

FIG. 3 shows an example elevation 300 of two adjacent image sensor pixels 302, 304. In some embodiments, the image sensor pixels 302, 304 may be included in an image sensor used in one of the cameras described with reference to FIGS. 1A and 1B, or in the image sensor described with reference to FIG. 2 (e.g., the elevation 300 may be taken along the view-line II-II in FIG. 2). By way of example, various structures of the image sensor pixel 302 are described below. The other image sensor pixel 304 may be constructed in a similar manner.

The image sensor pixel 302 includes a photodiode 306 formed within an epitaxial stack 308. The epitaxial stack 308 may include an electrical interface 310 (e.g., transistors, conductive traces, and other structures) formed in a set of conductive layers (e.g., metal layers) separated by a set of non-conductive layers (e.g., oxide layers). Electrical interconnect (e.g., vias or electrical contacts) may provide electrical connections between the conductive layers and to circuitry outside the epitaxial stack 308. The electrical interface 310 may be formed opposite a light-receiving surface 312 of the photodiode 306.

For purposes of this description, a photodiode (e.g., the photodiode 306) is presumed to include both an electromagnetic radiation (light)-to-charge converting material, such as silicon (Si), and any conductive layers that are formed directly on (i.e., that are deposited on and in electrical contact with) the photodiode. For example, the photodiode 306 may include one or more layers of silicon (Si) on which a layer of alumina is deposited, with the layer of alumina being deposited on the light-receiving surface of the silicon.

An anti-reflective coating 314 including one or more layers may be formed on the light-receiving surface 312 of the photodiode 306. An optional optical filter layer 316, such as a color filter layer, may be formed on the anti-reflective coating 314. An optional planarization layer 318 may be formed on the optical filter layer 316 (or on the anti-reflective coating 314 when no optical filter layer 316 is provided). An optional lens 320, such as a microlens, may be formed on or attached to the planarization layer 318 (or to the optical filter layer 316 or anti-reflective coating 314 when the planarization layer 318 or optical filter layer 316 is not provided). Optionally, a planarization layer 322 (or encapsulation layer) may be formed on the light-receiving surface of the lens 320.

In some embodiments, an optional opaque grid 324 may separate adjacent image sensor pixels 302, 304.

Light 326 entering the image sensor pixel 302 may propagate through the planarization layer 322, lens 320, planarization layer 318, optical filter layer 316, and anti-reflective coating 314, and may be absorbed by and converted to a charge by the photodiode 306. The charge may then be stored and/or read out using a pixel circuit, such as a pixel circuit provided in the electrical interface 310.

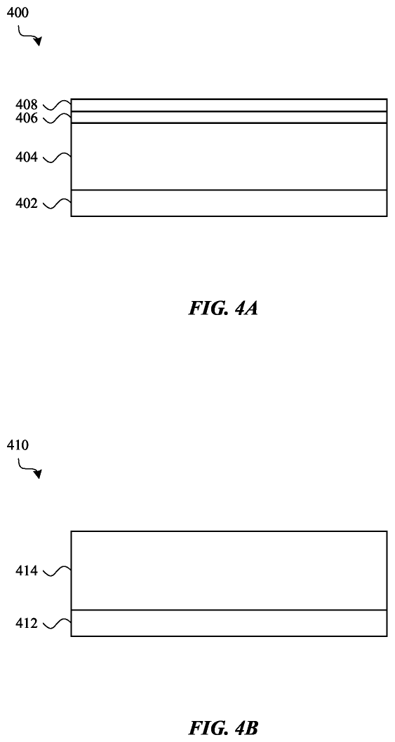

FIGS. 4A and 4B show examples of anti-reflective coatings that may be formed on a photodiode of an image sensor pixel. In some embodiments, the anti-reflective coatings may be the anti-reflective coating on one of the image sensor pixels described with reference to FIG. 3.

As shown in FIG. 4A, the anti-reflective coating 400 may include a stack of four layers. A first layer 402 may be deposited on a photodiode (e.g., on the photodiode described with reference to FIG. 3). A second layer 404 may be deposited on the first layer 402; a third layer 406 may be deposited on the second layer 404; and a fourth layer 408 may be deposited on the third layer 406. An optical filter layer, planarization layer, or other component, material, or layer may be deposited on the fourth layer 408.

The four layers 402, 404, 406, 408 may include alternating layers of a higher refractive index material and a lower refractive index material, with the higher refractive index material having a refractive index that is higher than the refractive index of the lower refractive index material (and vice versa). In some cases, the lower refractive index material may be silicon dioxide (SiO₂), and the higher refractive index material may be tantalum pentoxide (Ta₂O₅) or halfium dioxide (HfO₂). The higher refractive index material may have a refractive index that is intermediate the refractive index of the photodiode on which the anti-reflective coating 400 is deposited and the refractive index of the lower refractive index material. The higher refractive index material may be deposited on a photodiode as the first layer 402, and may also define the third layer 406. The lower refractive index material may define the second and fourth layers 404, 408.

In some cases, both of the layers formed of the higher refractive index material may include Ta2O5, both of the layers including the higher refractive index material may include HfO2, or one of the layers including a higher refractive index material may include Ta2O5 and the other layer may include HfO2. The first layer 402 may alternatively be formed of, or include, another material that has a refractive index intermediate the refractive index of a photodiode (e.g., the refractive index of silicon) and the refractive index of the material used to form the second layer 404. The third layer 406 may alternatively be formed of, or include, another material that has a refractive index intermediate greater than the refractive indices of the second layer 404 and the fourth layer 408. Conversely, the second layer 404 may be formed of SiO2 or include another material that has a refractive index lower than the refractive indices of the materials used to form the first and third layers 402, 406. The fourth layer 408 may also be formed of SiO2 or include another material that has a refractive index intermediate lower than the refractive index of the third layer 406.

In some embodiments, the second layer 404 may be thicker than the other layers 402, 406, 408 (e.g., twice as thick or more). In some embodiments, the first and second layers 402, 404 may each be thicker than the third or fourth layer 406, 408. In some embodiments, the thickness of each layer 402, 404, 406, 408, or the thicknesses of adjacent layers 402, 404, 406, 408 may be optimized to improve an anti-reflection property of the anti-reflective coating 400 for a particular wavelength or range of wavelengths of light. The thicknesses of the different layers 402, 404, 406, 408 may in some cases be optimized or tuned using a Finite Difference Time Domain (FDTD) simulation of diffraction effects through the anti-reflective coating 400 and a photodiode on which the anti-reflective coating 400 is formed. FDTD simulation may be more appropriate than ray-tracing because the small area of an image sensor pixel compared to the height (or thickness) of the anti-reflective coating 400 means that diffraction effects are more significant than they are for a glass camera lens or the like.

As mentioned above, the different higher refractive index layers 402, 406 may include different materials and/or the different lower refractive index layers 404, 408 may include different materials. In these embodiments, the first layer 402 may have a first refractive index; the second layer 404 may have a second refractive index lower than the first refractive index; the third layer 406 may have a third refractive index higher than the second refractive index; and the fourth layer 408 may have a fourth refractive index lower than the third refractive index. In some embodiments, the first and third refractive indices may both be greater than the second and fourth refractive indices.

As shown in FIG. 4B, the anti-reflective coating 410 may include a stack of two layers. A first layer 412 may be deposited on a photodiode (e.g., directly on the photodiode described with reference to FIG. 3). A second layer 414 may be deposited on the first layer 412. A planarization layer or other material (or layer) may be deposited on the fourth layer 408.

The first layer 412 may include a higher refractive index material and the second layer 414 may include a lower refractive index material, with the higher refractive index material having a refractive index that is higher than the lower refractive index material (and vice versa). In some cases, the lower refractive index material may be formed of silicon dioxide (SiO₂), and the higher refractive index material may be formed of tantalum pentoxide (Ta2O5) or halfium dioxide (HfO₂).

Comparing the anti-reflective coatings described with reference to FIGS. 4A and 4B, the anti-reflective coating 400 described with reference to FIG. 4A may provide better anti-reflective performance across the visible spectrum and range of incoming angles for an image sensor pixel, and may do so with a stack height that is about the same as the two layer stack height. In some cases, the anti-reflective coating 400 may provide a 40% anti-reflection improvement over the anti-reflective coating 410, with a negligible increase in stack height (e.g., the increase in stack height for the anti-reflective coating 400, over the anti-reflective coating 410, may be less than about 10%). In some cases, the stack height of the anti-reflective coating 400 may be about 200 nanometers (nm), and the stack of the anti-reflective coating 410 may be about 193 nm, such that the four layer anti-reflective coating 400 is only about 3.5% thicker than the two layer anti-reflective coating 410. As an additional benefit, the lower reflectance of the anti-reflective coating 400 across the visible range, compared to the reflectance of the anti-reflective coating 410, may increase an image sensor pixel's sensitivity and quantum efficiency.

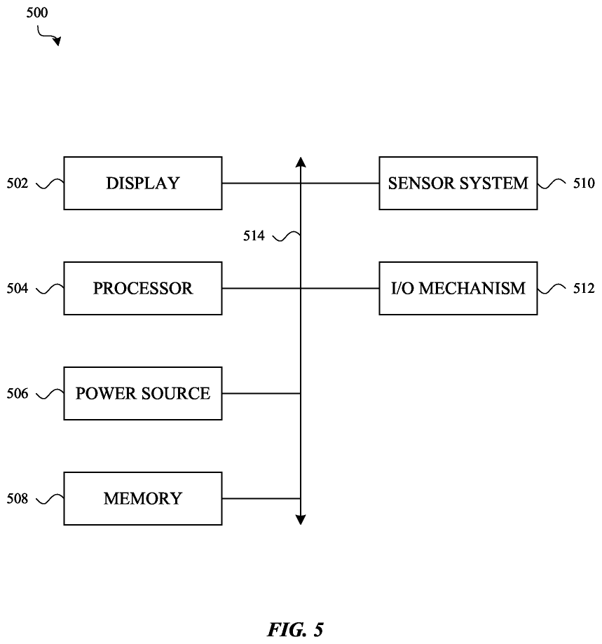

FIG. 5 shows an example block diagram of an electronic device 500, which in some cases may be the electronic device described with reference to FIGS. 1A and 1B. The electronic device 500 may include an electronic display 502 (e.g., a light-emitting display), a processor 504, a power source 506, a memory 508 or storage device, a sensor system 510, and/or an input/output (I/O) mechanism 512 (e.g., an input/output device, input/output port, or haptic input/output interface). The processor 504 may control some or all of the operations of the electronic device 500. The processor 504 may communicate, either directly or indirectly, with some or all of the other components of the electronic device 500. For example, a system bus or other communication mechanism 514 can provide communication between the electronic display 502, the processor 504, the power source 506, the memory 508, the sensor system 510, and the I/O mechanism 512.

The processor 504 may be implemented as any electronic device capable of processing, receiving, or transmitting data or instructions, whether such data or instructions is in the form of software or firmware or otherwise encoded. For example, the processor 504 may include a microprocessor, a central processing unit (CPU), an application-specific integrated circuit (ASIC), a digital signal processor (DSP), a controller, or a combination of such devices. As described herein, the term “processor” is meant to encompass a single processor or processing unit, multiple processors, multiple processing units, or other suitably configured computing element or elements. In some cases, the processor 504 may provide part or all of the processing system or processor described herein.

It should be noted that the components of the electronic device 500 can be controlled by multiple processors. For example, select components of the electronic device 500 (e.g., the sensor system 510) may be controlled by a first processor and other components of the electronic device 500 (e.g., the electronic display 502) may be controlled by a second processor, where the first and second processors may or may not be in communication with each other.

The power source 506 can be implemented with any device capable of providing energy to the electronic device 500. For example, the power source 506 may include one or more batteries or rechargeable batteries. Additionally or alternatively, the power source 506 may include a power connector or power cord that connects the electronic device 500 to another power source, such as a wall outlet.

The memory 508 may store electronic data that can be used by the electronic device 500. For example, the memory 508 may store electrical data or content such as, for example, audio and video files, documents and applications, device settings and user preferences, timing signals, control signals, instructions, and/or data structures or databases. The memory 508 may include any type of memory. By way of example only, the memory 508 may include random access memory, read-only memory, Flash memory, removable memory, other types of storage elements, or combinations of such memory types.

The electronic device 500 may also include one or more sensor systems 510 positioned almost anywhere on the electronic device 500. The sensor system(s) 510 may be configured to sense one or more types of parameters, such as but not limited to, vibration; light; touch; force; heat; movement; relative motion; biometric data (e.g., biological parameters) of a user; air quality; proximity; position; connectedness; surface quality; and so on. By way of example, the sensor system(s) 510 may include an SMI sensor, a heat sensor, a position sensor, a light or optical sensor, an image sensor (e.g., one or more of the image sensors or cameras described herein), an accelerometer, a pressure transducer, a gyroscope, a magnetometer, a health monitoring sensor, and an air quality sensor, and so on. Additionally, the one or more sensor systems 510 may utilize any suitable sensing technology, including, but not limited to, interferometric, magnetic, capacitive, ultrasonic, resistive, optical, acoustic, piezoelectric, or thermal technologies.

The I/O mechanism 512 may transmit or receive data from a user or another electronic device. The I/O mechanism 512 may include the electronic display 502, a touch sensing input surface, a crown, one or more buttons (e.g., a graphical user interface “home” button), one or more microphones or speakers, one or more ports such as a microphone port, and/or a keyboard. Additionally or alternatively, the I/O mechanism 512 may transmit electronic signals via a communications interface, such as a wireless, wired, and/or optical communications interface. Examples of wireless and wired communications interfaces include, but are not limited to, cellular and Wi-Fi communications interfaces.

The foregoing description, for purposes of explanation, uses specific nomenclature to provide a thorough understanding of the described embodiments. However, it will be apparent to one skilled in the art, after reading this description, that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art, after reading this description, that many modifications and variations are possible in view of the above teachings.

What is claimed is:

1. An image sensor pixel, comprising:
a photodiode;
a lens positioned in a light-receiving path of the photodiode; and
an anti-reflective coating disposed between the photodiode and the lens and including four layers, the four layers including alternating layers of,
a higher refractive index material; and
a lower refractive index material; wherein,
the higher refractive index material has a refractive index that is higher than the lower refractive index material.

2. The image sensor pixel of claim 1, wherein:
the higher refractive index material comprises Ta₂O₅; and
the lower refractive index material comprises SiO₂.

3. The image sensor pixel of claim 1, wherein:
the higher refractive index material comprises HfO₂; and
the lower refractive index material comprises SiO₂.

4. The image sensor pixel of claim 1, wherein a layer of the anti-reflective coating closest to the photodiode includes the higher refractive index material.

5. The image sensor pixel of claim 4, wherein the photodiode comprises silicon.

6. The image sensor pixel of claim 5, wherein the higher refractive index material is deposited on the photodiode.

7. The image sensor pixel of claim 1, wherein the higher refractive index material has a first refractive index intermediate a second refractive index of the photodiode and a third refractive index of the lower refractive index material.

8. The image sensor pixel of claim 1, further comprising:
a color filter positioned between the anti-reflective coating and the lens.

9. The image sensor pixel of claim 1, wherein the lens comprises a microlens.

10. An image sensor, comprising:
an array of pixels, at least one pixel in the array of pixels including,
a photodiode; and
a four layer anti-reflective coating formed directly on the photodiode and including alternating layers of a higher refractive index material and a lower refractive index material; wherein,
the higher refractive index material has a refractive index that is higher than the lower refractive index material.

11. An image sensor pixel, comprising:
a photodiode;
a lens positioned in a light-receiving path of the photodiode; and
an anti-reflective coating disposed between the photodiode and the lens and including four layers, the four layers including,
a first layer having a first refractive index, the first layer positioned closer to the photodiode than the other layers in the four layers;
a second layer having a second refractive index, the second refractive index lower than the first refractive index, and the second layer disposed on the first layer with the first layer between the second layer and the photodiode;
a third layer having a third refractive index, the third refractive index higher than the second refractive index, and the third layer disposed on the second layer with the second layer between the third layer and the first layer; and
a fourth layer having a fourth refractive index, the fourth refractive index lower than the third refractive index, and the fourth layer disposed on the third layer with the third layer between the fourth layer and the second layer.

12. The image sensor pixel of claim 11, wherein the first refractive index is different from the third refractive index.

13. The image sensor pixel of claim 11, wherein the second refractive index is different from the fourth refractive index.

14. The image sensor pixel of claim 11, wherein both of the first refractive index and the third refractive index are greater than both of the second refractive index and the fourth refractive index.
